(19) United States
(12) Patent Application Publication
(10) Pub. No.: US 2009/0045421 A1
(43) Pub. Date: Feb. 19, 2009

(54) Surface mount type light emitting diode package device

(76) Inventors: Hsin-Hua Ho, Miaoli County (TW); Wen-Jeng Hwang, Yun-Lin County (TW)

Correspondence Address: NORTH AMERICA INTELLECTUAL PROPERTY CORPORATION, P.O. BOX 506, MERRIFIELD, VA, 22116, US

(21) Appl. No.: 11/867,702

(22) Filed: Oct. 5, 2007

(30) Foreign Application Priority Data
Aug. 17, 2007 (TW) 096213733

(51) Int. Cl. H01L 33/00

(52) U.S. Cl. 257/98; 257/E33.057

(57) ABSTRACT

The invention discloses a surface mount type light emitting diode (LED) package device, which has a cup-shaped structure and comprises a specific lens bulged out over the cup opening. The lens is an aspheric lens having a specific curved surface not fully symmetric with respect to its central point, while it exhibits a similarly symmetric curved surface with respect to a bisector line or a diagonal line passing through the central point. The LED package device according to the present invention may have a wider view angle.

### BACKGROUND OF THE INVENTION

1. Field of the Invention

The present invention relates to a light emitting device, and particularly to a surface mount type light emitting diode (LED) package device having a relatively wide light emitting angle.

2. Description of the Prior Art

Recently, the new application fields of LEDs have been developed. LEDs are classified as a type of cold illumination and have the advantages of low power consumption, long device lifetime, no idling time, and quick response speed. In addition, LEDs also have the advantages of small size, shock resistance, being suitable for mass production, and being easily fabricated as a tiny device or an array device. For a certain application, the LEDs need to have particular properties in beam patterns and view angles or light emitting angles. For example, when an LED is used in a direct-type backlight module of an LCD-TV, a wide light emitting angle is often required to shorten the distance between the backlight module and the TFT-LCD module.

In conventional technology, a lens structure has ever been used to alter the light emitting angle of a light emitting device. For example, FIG. 1 illustrates a structure of a package device with a spherical lens structure. The spherical lens 2 is formed simply by means of glue dispensing or casting. The spherical lens 2 can focus light beams but cannot widen the light emitting angle. FIG. 2 illustrates a structure of a package device having a plano-concave lens 3 disposed on an encapsulation material layer. FIG. 3 illustrates a structure of a package device having a Fresnel lens 4. FIG. 4 illustrates a structure of a package device having a plano-convex lens 5 disposed on a cup-shaped substrate without encapsulation material. FIG. 5 illustrates a structure of a package device having a plano-convex lens 6 disposed upside down. FIG. 6 illustrates a structure of a light emitting package device combining a bowl-shaped lens 7 and a reflection sheet 8. Since the lens 7 has a complicated structure, it is needed to firstly perform a curing process and then an adhesion process to adhere the lens 7 on the surface of the LED with an adhesive for manufacturing the light emitting package device. Automatic production will not be easy with such processes.

Therefore, an LED device easily manufactured and having a wide view angle is still needed for use in a backlight module, for example, to shorten the distance to the TFT-LCD module.

### SUMMARY OF THE INVENTION

An objective of the present invention is to provide a surface mount type LED package device comprising a lens structure having a special shape, and the light emitting angle may be widely controlled thereby.

The surface mount type LED package device according to the present invention comprises a cup-shaped substrate, a lead frame, one or more LED chips, at least one conductive wire, and an encapsulator having a lens curved surface. The cup-shaped substrate comprises a cup wall and a cup bottom to form a containing space. The LED chip or chips are disposed on the lead frame on the cup bottom and electrically connected to the lead frame through the conductive wire to acquire electric current through the lead frame for emitting light. Due to the design of the chip electrode, there may be one or two conductive wires. The encapsulator having the lens curved surface covers the LED chip or chips. When the cup opening is in a regular shape such as rectangle or square, the lens curved surface comprises two similarly symmetric portions respectively corresponding to two sides of a diagonal line or a bisector line of the shape of the cup opening. Furthermore, the lens curved surface comprises a first portion above a diagonal line of the shape of the cup opening and a second portion above a bisector line of the shape of the cup opening, and the curvature of the first portion is different from the curvature of the second portion. Therefore, the lens curved surface is related to the shape of the cup opening and the height of the encapsulator. Accordingly, the light emitting angle of the LED may be controlled by controlling the lens curved surface.

The surface mount type LED package device according to the present invention comprises a novel structure of a lens or a lens set instead of a conventional lens, and the light emitting angle can be well controlled by regulating the curvature of each lens curved surface, and thereby the LED package device may be advantageously utilized.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-6 illustrate some examples of lens components in some conventional light emitting devices;

FIG. 7 is a schematic diagram showing a cross-sectional view of an embodiment of the surface mount type LED package device according to the present invention;

FIG. 8 is a schematic diagram showing a top view of the surface mount type LED package device as shown in FIG. 7;

FIG. 9 illustrates plotting of lens curved surface height versus position thereat for an embodiment of the surface mount type LED package device according to the present invention;

FIG. 10 is a schematic diagram showing a cross-sectional view of an embodiment of the surface mount type LED package device according to the present invention;

FIG. 11 is a schematic diagram showing a cross-sectional view of an embodiment of the surface mount type LED package device according to the present invention, in which a lens set is employed;

FIG. 12 is a schematic diagram showing a cross-sectional view of another embodiment of the surface mount type LED package device according to the present invention, in which a lens set is employed; and

FIG. 13 illustrates the similar symmetry of the lens curved surface when the shape of the cup opening is rectangular in the surface mount type LED package device according to the present invention.

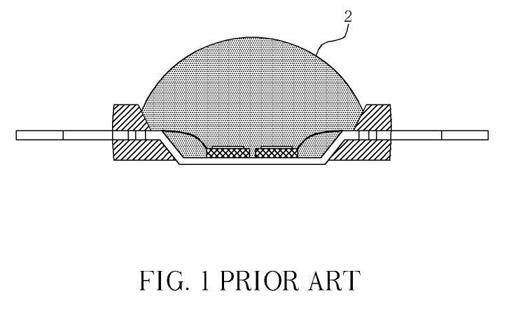

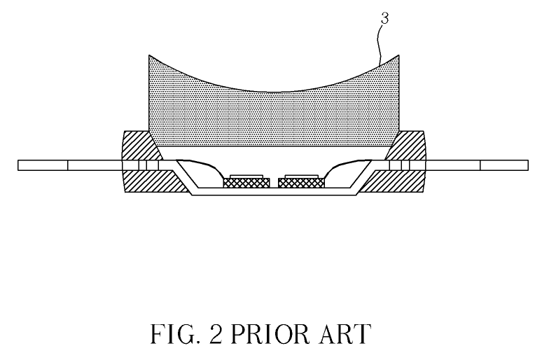

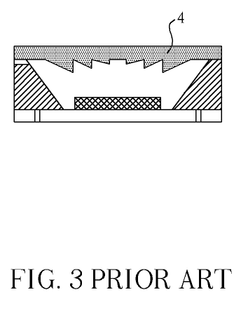

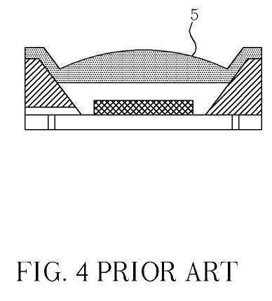

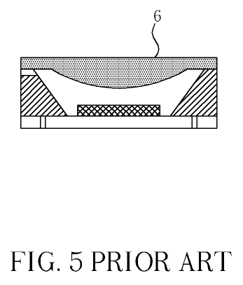

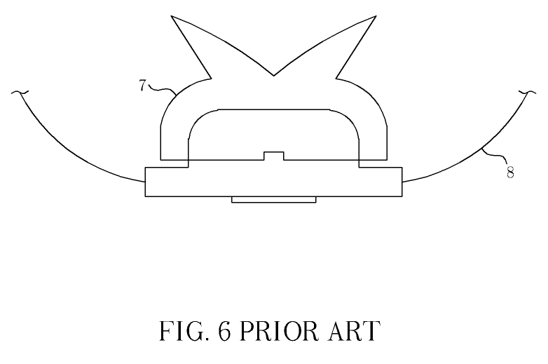

### DETAILED DESCRIPTION

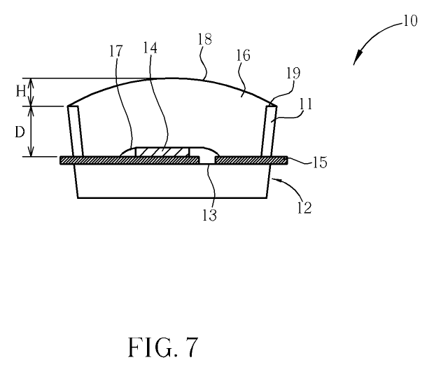

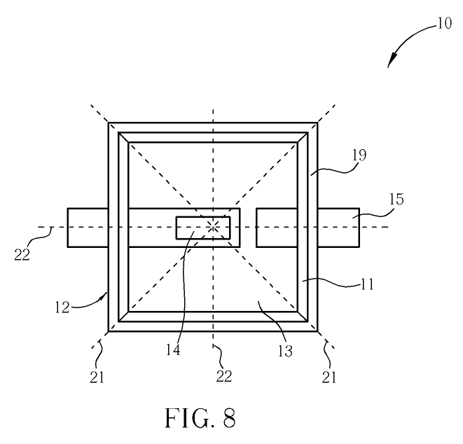

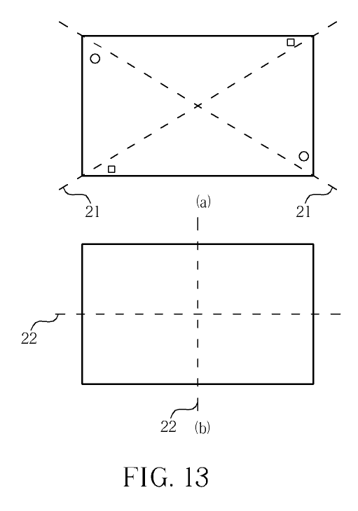

Please refer to FIGS. 7 and 8, showing a cross-sectional view and a top view of an embodiment of the surface mount type LED package device according to the present invention. The LED package device 10 comprises a cup-shaped substrate 12, an LED chip 14, a lead frame 15, an encapsulator 16, and a conductive wire 17. The cup-shaped substrate 12 comprises a cup wall 11 and a cup bottom 13 to form a containing space. The LED chip 14 is disposed on the lead frame 15 on the cup bottom 13. The encapsulator 16 having the lens curved surface 18 covers the LED chip 14 and bulges out over the cup opening 19 of the cup-shaped substrate 12. H is the height of the lens curved surface measured from the cup opening 19. D is the depth of the cup bottom 13 from the cup opening 19. When the cup opening 19 is square, as shown in FIG. 8, two portions of the lens curved surface 18, which are located respectively corresponding to two sides of a diagonal line 21 or a bisector line 22 of the shape of the cup opening 19, are similarly symmetric to each other. Alternatively, the cup opening may be rectangular. In such case, the lens curved surface still has the similar symmetric properties. As shown by the schematic diagrams (a) and (b) in FIG. 13, the diagonal line 21 is an axis of diagonal similar symmetry. For example, as shown in FIG. 13, with respect to a lens curved surface in the present invention, two circle-marked areas are similarly symmetric to each other, and two square-marked areas are similarly symmetric to each other. The bisector line 22 is an axis of mirror similar symmetry.

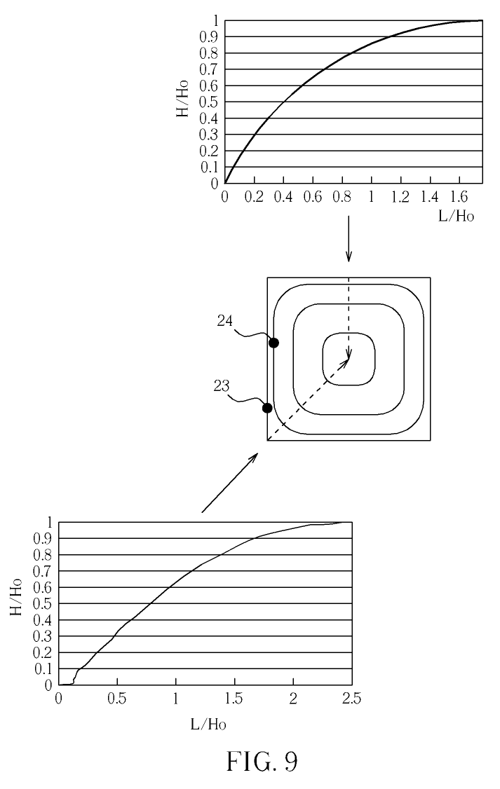

Please refer to FIG. 9, showing the plotting of H/H₀ versus L/H₀ correspondingly along the diagonal line 21 and the bisector line 22 of the cup opening, for an embodiment of the surface mount type LED package device according to the present invention. H is the height of a point on the lens curved surface with respect to the cup opening 19. L is the distance measured in the direction to the central point between the edge 23 and the point as projected on the cup opening plane. H₀ is the height of the central point of the lens curved surface. The height variation of the curved surface from the edge to the central point correspondingly along the diagonal line 21 of the shape of the cup opening 19 is slower than the height variation of the curved surface from the edge to the central point correspondingly along the bisector line 22. Accordingly, the contour lines of the lens curved surface are not conventional circles but depend on the shape of the circumference of the cup opening. For example, as shown in FIG. 9, the contour line 24 is a square with four round corners. In the case that the cup opening is rectangular, the contour line 24 may be a rectangle with four round corners. Thus, the curvature of the lens curved surface may be controlled by the height of the encapsulator and the distance between the cup opening and the central point. In turn, various view angles may be obtained by controlling the lens curved surface, and the range may be from 60 to 175 degrees.

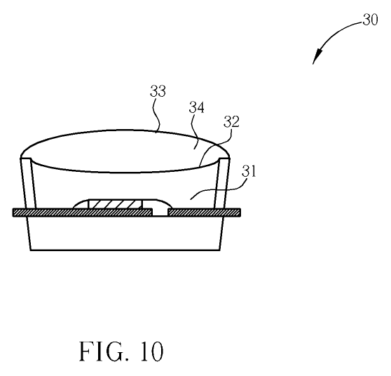

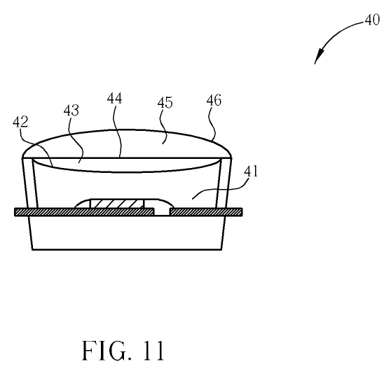

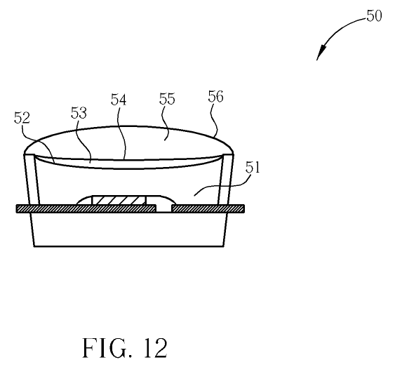

The lens curved surface may be formed by stacking a plurality of lens layers, taking the advantage of different refraction indexes thereof. In other words, the encapsulator may be a singular encapsulation material layer or a combination of an encapsulation material layer and one or more lens layers stacked together. For example, FIG. 10 illustrates an embodiment having a set of lens curved surfaces. The encapsulation material layer 31 of the LED package device 30 covers the LED chip and has a lens curved surface 32 lower than the cup opening and concave-up. Above the lens curved surface 32, there is an upper lens layer 34 comprising a material having a different refraction index from that of the encapsulation material layer 31. The upper lens layer 34 has a lens curved surface 33 higher than the cup opening. FIG. 11 shows another embodiment having a set of a plurality of lens curved surfaces. The encapsulation material layer 41 of the LED package device 40 covers the LED chip 14. The lens curved surface 42 is lower than the cup opening and concave-up. Above the lens curved surface 42, there is a middle lens layer 43 comprising a material having a refraction index different from that of the encapsulation material layer 41. The middle lens layer 43 has a lens curved surface 44, which is at a same height as or higher than the cup opening. Above the lens curved surface 44, there is an upper lens layer 45 comprising a material having a refraction index different from that of the middle lens layer 43. The upper lens layer 45 has a lens curved surface 46 higher than the lens curved surface 44 and the cup opening. FIG. 12 illustrates another embodiment having a combination of a plurality of lens curved surfaces. The LED package device 50 is similar to the embodiment shown in FIG. 11. The encapsulator is formed by the combination of an encapsulation material layer 51, a middle lens layer 53, and an upper lens layer 55, with an uppermost surface as a lens curved surface 56. The lower lens curved surface 52 of the middle lens layer 53 is at the height lower than the cup opening and concave-up, while the upper lens curved surface 54 of the middle lens layer 53 is at the height of the cup opening or lower than the cup opening. Each of the aforesaid lens curved surfaces in the present invention has two similarly symmetric portions respectively corresponding to the two sides of the diagonal line or the bisector line of the rectangular or square cup opening.

In the LED package device according to the present invention, the encapsulation material layer or the lens layer may include a conventional transparent encapsulation material, such as, resins, silicone, fluorinated silicone, glass, or the like. The encapsulation material layer or the lens layer may further include a diffusing agent. When the diffusing agent or the like is included in the package device, the light intensity can be enhanced, and, for a multi-chip LED device, the light-mixing performance can be improved. The middle lens layer between the upper lens layer and the encapsulation material layer can be a layer of air.

The fixation of the lens to the underlying structure may be improved by one or more pin-and-hole structures.

The shape of the cup opening is not limited to rectangle, square, or circle, and may be other shapes, such as, polygon or irregular shape, to be combined with the lens curved surface, the height of the lens curved surface, the depth of the cup bottom from the cup opening, and the size of the cup opening to produce a desired beam pattern and view angle. The cup wall may be a high reflection material or a transparent material, depending on the application of the light emitting device. Also, the surface of the cup wall may be coated with a high reflection material or an anti-reflection material. In addition, holes/protrusions may be formed on the cup wall for serving as pin/hole structures in order to improve the adhesion or fixation of the encapsulation material to the cup wall. The holes/protrusions are not limited to be cylindrical and may be in a shape of a triangular prism, a square prism, a rectangular prism, an irregular polygonal prism, or the like. Furthermore, the plurality of holes/protrusions may be formed in a shape of circle, square, octagon, hexagon, or an irregular shape.

The material for the lens may be the transparent material used for the encapsulation material layer. The lenses in the lens set may be formed of same or different materials. The lens or lens set may be formed directly on the encapsulation material layer by a glue dispensing or casting process performed in stages. Alternatively, as desired, the lens may be separately processed in advance and then placed on the encapsulation material layer to accomplish the package of the light emitting device.

As compared with conventional techniques, in the surface mount type LED package device according to the present invention, a lens or lens set having an aspheric surface as a whole is utilized instead of a conventional lens having a spherical surface as a whole, such that the view angle, i.e. the light emitting angle, can be controlled by regulating the curvature of each lens, and thereby it may advantage the application that, for example, the distance between a backlight module and a LCD module can be shortened and the manufacture process becomes more convenient.

Those skilled in the art will readily observe that numerous modifications and alterations of the device and method may be made while retaining the teachings of the invention.

What is claimed is:

1. A surface mount type light emitting diode package device, comprising:
a cup-shaped substrate comprising a cup wall, a cup opening, and a cup bottom to form a containing space;
a lead frame disposed on the cup bottom;
at least one light emitting diode chip disposed on the lead frame;
at least one conductive wire electrically connecting the light emitting diode chip to the lead frame; and
an encapsulator covering the light emitting diode chip, wherein the encapsulator has a first lens curved surface bulged out over the cup opening, the first lens curved surface comprises a first portion above a diagonal line of the shape of the cup opening and a second portion above a bisector line of the shape of the cup opening, and the curvature of the first portion is different from the curvature of the second portion.

2. The device of claim 1, wherein the cup opening has a shape of square, rectangle, or polygon.

3. The device of claim 1, wherein the cup opening has a circle shape or an irregular shape.

4. The device of claim 1, wherein the height variation of the first lens curved surface from its edge to its central point above a diagonal line of the shape of the cup opening is slower than the height variation of the first lens curved surface from its edge to its central point above a bisector line of the shape of the cup opening.

5. The device of claim 1, wherein the first lens curved surface comprises two similarly symmetric portions located respectively corresponding to two sides of a diagonal line of the shape of the cup opening.

6. The device of claim 1, wherein the first lens curved surface comprises two similarly symmetric portions located respectively corresponding to two sides of a bisector line of the shape of the cup opening.

7. The device of claim 1, wherein the first lens curved surface has contour lines respectively in a shape of square or rectangle with four round corners.

8. The device of claim 1, wherein the encapsulator comprises a diffusing agent.

9. The device of claim 1, wherein a pin-and-hole structure is formed between the encapsulator and a structure underlying the encapsulator to improve fixation.

10. The device of claim 1, wherein, the encapsulator comprises an encapsulation material layer, and the first lens curved surface is the upper surface of the encapsulation material layer.

11. The device of claim 1, wherein, the encapsulator comprises an encapsulation material layer and at least one lens layer stacked on the encapsulation material layer, and the first lens curved surface is the upper surface of the uppermost lens layer.

12. The device of claim 11, wherein the at least one lens layer comprises a first lens layer, the lower surface of the first lens layer forms a second lens curved surface, and the second lens curved surface is lower than the cup opening and in a concave up shape.

13. The device of claim 11, wherein, the at least one lens layer comprises a first lens layer and a second lens layer stacked together on the encapsulation material layer such that the second lens layer underlies the first lens layer, the lower surface of the second lens layer forms a second lens curved surface lower than the cup opening and in a concave-up shape, and the lower surface of the first lens layer forms a third lens curved surface at a same height as or higher than the cup opening.

14. The device of claim 11, wherein, the at least one lens layer comprises a first lens layer and a second lens layer stacked together on the encapsulation material layer such that the second lens layer underlies the first lens layer, the lower surface of the second lens layer forms a second lens curved surface lower than the cup opening and in a concave-up shape, and the lower surface of the first lens layer forms a third lens curved surface lower than the cup opening.

15. The device of claim 13, wherein, the first lens layer and the second lens layer comprise materials different from each other.

16. The device of claim 14, wherein, the first lens layer and the second lens layer comprise materials different from each other.

17. The device of claim 1, wherein the cup wall comprises a reflection material.

18. The device of claim 1, wherein the cup wall comprises a transparent material.
